(19) United States
(12) Patent Application Publication
(10) Pub. No.: US 2009/0301995 A1
(43) Pub. Date: Dec. 10, 2009

(54) Method for Making a Plate-Like Detachable Structure, in Particular Made of Silicon, and Use of Said Method

(75) Inventors: Bernard Aspar, St. Ismier (FR); Chrystelle Lagahe-Blanchard, Crolles (FR)

Correspondence Address: MEYERTONS, HOOD, KIVLIN, KOWERT & GOETZEL, P.C., P.O. BOX 398, AUSTIN, TX, 78767-0398, US

(73) Assignee: Tracit Technologies, Bernin (FR)

(21) Appl. No.: 12/087,093

(22) PCT Filed: Dec. 27, 2006
(86) PCT No.: PCT/FR2006/002886

§ 371 Date: Dec. 1, 2008

(30) Foreign Application Priority Data
Dec. 27, 2005 (FR) 05 13367

(51) Int. Cl. H01L 21/70; B32B 38/00; C23F 1/04

(52) U.S. Cl. 216/13; 427/97.6; 156/344

(57) ABSTRACT

Process for fabricating a structure in the form of a wafer, including at least a substrate, a superstrate and at least one intermediate layer interposed between the substrate and the superstrate, the process including: forming, on a substrate, at least one intermediate layer including at least one base material in which extrinsic atoms or molecules are distributed, these differing from the atoms or molecules of the base material, so as to constitute a substructure; applying a base heat treatment to this substructure such that, in the temperature range of this heat treatment, the presence of the chosen extrinsic atoms or molecules in the chosen base material causes a structural transformation of said intermediate layer; and joining a superstrate to said heat-treated intermediate layer so as to obtain said structure in the form of a wafer.

### BACKGROUND OF THE INVENTION

1. Field of the Invention

The present invention generally relates to the field of the fabrication of multilayer wafers and in particular separable or detachable multilayer wafers, particularly for the fabrication of thin wafers or thin components.

2. Description of the Relevant Art In the microtechnology field, especially the field of microelectronics, power electronics, optoelectronics and MEMS-type components, it is known to use silicon wafers bonded to an insulating layer of the SOI type and more particularly detachable structures comprising an insulating layer interposed between a silicon substrate and a silicon superstrate. Such detachable structures have been proposed in document FR-A-2 860 249.

### SUMMARY OF THE INVENTION

The objective of the embodiments described herein is to provide fabrication techniques and structures that are markedly different from those presently known.

A first embodiment is directed to a process for fabricating a structure in the form of a wafer, including at least a substrate, a superstrate and at least one intermediate layer interposed between the substrate and the superstrate.

According to the first embodiment, this process includes:

forming, on a substrate, at least one intermediate layer comprising at least one base material in which what are called extrinsic atoms or molecules are distributed, these differing from the atoms or molecules of the base material, so as to constitute a substructure;

applying a base heat treatment to this substructure such that, in the temperature range of this heat treatment, the presence of the chosen extrinsic atoms or molecules in the chosen base material causes a structural transformation of said intermediate layer; and

joining a superstrate to said heat-treated intermediate layer so as to obtain said structure in the form of a wafer.

The process according to first embodiment, may further include applying a complementary heat treatment to said structure, consolidating the bond between the superstrate and said intermediate layer and/or inducing a complementary structural transformation of said intermediate layer. Said heat treatment and/or said complementary heat treatment may induce mechanical weakening, i.e. weakening through a particular mechanical action, and/or chemical weakening, i.e. weakening through a particular chemical action, and/or thermal weakening, i.e. weakening through a particular heat treatment, of said intermediate layer.

In one embodiment, the heat treatment of said intermediate layer causes microbubbles or microcavities to form in this layer.

In one embodiment, the substrate and/or the superstrate are made of single-crystal silicon and the intermediate layer is made of doped silica.

In one embodiment, the substrate and/or the superstrate are made of silicon, of a semiconductor material of III-V class, of silicon carbide (SiC) or of gallium nitride (GaN).

In one embodiment, the base material of said intermediate layer is silica and the extrinsic atoms of this layer are phosphorus or boron atoms, thus forming a phosphosilicate glass (PSG) or borophosphosilicate glass (BPSG) intermediate layer.

In one embodiment, the phosphorus concentration may advantageously be between 6% and 14%, without however being limited to this particular choice.

In one embodiment, the boron concentration is preferably between 0 and 4%, without however being limited to this particular choice.

In one embodiment, the heat treatment is preferably carried out at a temperature between 400° C. and 1200° C., preferably between 900° C. and 1200° C.

In one embodiment, the process further includes attaching the superstrate to said intermediate layer by direct (molecular adhesion) bonding.

In one embodiment, the substrate and/or the superstrate preferably include, respectively, on the side of said intermediate layer, a thermal silicon oxide or any other protective layer, preferably for preventing or reducing the diffusion of atoms between the intermediate layer and the substrate and/or the superstrate.

In one embodiment, at least some of said microbubbles or microcavities are open cells and constitute, at least for some of them, channels.

In one embodiment, the process further includes an additional step of reducing the thickness of said superstrate and/or said substrate.

In one embodiment, the process further includes an additional step, possibly in several phases, of producing all or some of the integrated circuits or components on said superstrate and/or said substrate.

In one embodiment, the process further includes an additional step of producing grooves and/or etched features through the superstrate and/or the substrate.

A second embodiment is directed to a process for separating the substrate and the superstrate from said structure.

According to the second embodiment, this separation process may include applying forces between the substrate and the superstrate so as to break the intermediate layer between the substrate and the superstrate.

In an embodiment, the process may include chemically etching said intermediate layer so as to obtain at least partial removal of this intermediate layer between the substrate and the superstrate.

In an embodiment, the process may include applying a heat treatment causing said intermediate layer to weaken so as to break the intermediate layer between the substrate and the superstrate.

In an embodiment, the process may include combining at least two of the above effects, e.g., applying forces between the substrate and the superstrate and/or chemically etching said intermediate layer and/or applying a heat treatment to said intermediate layer.

A third embodiment is directed to the application of said process to the fabrication of detachable structures for the purpose of producing electronic and/or optoelectronic and/or MEMS-type integrated circuits, without however being limited to these above materials.

### BRIEF DESCRIPTION OF THE DRAWINGS

The present invention will be better understood on studying structures and methods of fabrication of such structures, described by way of non-limiting examples and shown in the drawings in which:

FIG. 1 shows a cross section of a substructure, in an initial state;

FIG. 2 shows a cross section of the substructure of FIG. 1 in a subsequent fabrication step;

FIG. 3 shows a cross section of a structure;

FIG. 4 shows a cross section of the structure of FIG. 3, in a subsequent fabrication step;

FIG. 5 shows a cross section of the structure of FIG. 4, in a subsequent fabrication step;

FIG. 6 shows a top view of the structure of FIG. 5;

FIG. 7 shows a cross section of the structure of FIG. 5 in a subsequent fabrication step;

FIG. 8 shows a cross section of the structure of FIG. 3, in another subsequent fabrication step; and

FIG. 9 shows a top view of the structure of FIG. 8.

While the invention may be susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF THE PREFERRED EMBODIMENTS

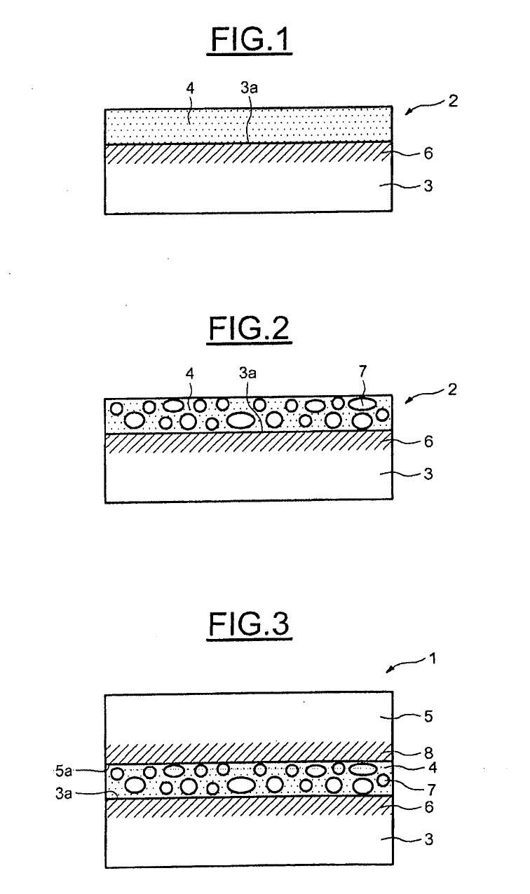

Referring to FIGS. 1 to 3, the various main steps in fabricating a complex structure 1 in the form of a wafer, having for example a diameter of about two hundred millimetres, will firstly be described.

As shown in FIG. 1, in a first step, a substructure 2 is fabricated which includes a substrate 3 in the form of a wafer and an intermediate layer 4 on a face 3a of this substrate.

As shown in FIG. 2, in a second step, a heat treatment is carried out on the substructure 2, for example in a furnace. The purpose of this step is to induce a structural transformation of the intermediate layer 4. This transformation preferably causes mechanical and/or chemical and/or thermal weakening of the intermediate layer 4.

As shown in FIG. 3, in a third step, the face 5a of a superstrate 5 in the form of a wafer is attached to the intermediate layer 4.

What is therefore obtained is the mounted structure 1.

In a fourth step, a complementary heat treatment is preferably carried out on the structure 1, for example in a furnace. This step may advantageously have the purpose of consolidating the bond between the face 5a of the superstrate 5 and the intermediate layer 4 and/or, possibly, of causing a complementary structural transformation of this intermediate layer 4.

In general, the intermediate layer 4 is made of at least one base material in which what are called extrinsic atoms or molecules are distributed, these being different from the atoms or molecules of the base material, and has a composition such that, when a suitable heat treatment is applied to the substructure 2, it induces, preferably irreversibly, a structural transformation of this intermediate layer.

This structural transformation preferably causes mechanical and/or chemical and/or thermal weakening of the intermediate layer 4.

According to the aforementioned first step, the substructure 2 may advantageously be obtained in the following manner, by carrying out the following treatments.

The substrate 3 may be formed by a single-crystal silicon wafer, the thickness of which may be a few hundred microns, for example between five hundred and one thousand microns.

Starting from such a substrate 3, the process preferably continues with an oxidation of this substrate so as to obtain a thermal silicon oxide film 6 on the face 3a, this film 6 possibly being obtained in an oxidation furnace at a temperature between 900° C. and 1100° C. and possibly having a thickness of between 0.5 and 3 microns. However, the film 6 could be made of silicon nitride, of silicon oxynitride.

Optionally, intermediate treatments may be applied, in particular an RCA chemical cleaning treatment and a chemical-mechanical polishing (CRP) operation may advantageously be carried out on the surface obtained.

Next, a silicon oxide layer is deposited on the oxidized face 3a of the substrate 3, said silicon oxide layer containing or doped with a high percentage of phosphorus and/or boron so as to obtain the intermediate layer 4 composed of a material of the phosphosilicate glass (PSG) or borophosphosilicate glass (BPSG) type.

To give an example, the percentage of phosphorus in the material constituting the intermediate layer 4 may be between six and fourteen and/or the percentage of boron in this layer may be between zero and four. Such deposition may be carried out using known techniques in deposition machines of the CVD, LPCVD or PECVD type. The intermediate layer 4 thus formed may have a thickness between one and ten microns.

In particular, a phosphosilicate glass (PSG) containing 6.5% phosphorus may be deposited in a PECVD deposition machine at 400° C. so as to obtain an intermediate layer 4 having a thickness close to 1.5 microns.

According to the second aforementioned step, the above substructure 2 is subjected to a heat treatment in a furnace, for example at a temperature between 400° C. and 1200° C., preferably between 900° C. and 1200° C.

In particular, the heat treatment may be carried out at a temperature close to 950° C. for two hours and in an argon and oxygen or nitrogen atmosphere.

Considering the chosen materials mentioned above, such a heat treatment, in the chosen temperature range, weakens the intermediate layer 4 by the fact that it induces, generally in an irreversible manner, the formation of a gaseous phase consisting of microbubbles or microcavities 7 in this intermediate layer 4 and, correspondingly, an increase in its thickness. Preferably, the intermediate layer 4 therefore undergoes a structural transformation and/or becomes spongy or porous.

The quantity and the volume of the microbubbles or microcavities 7 depend on the composition of the intermediate layer 4 and on the conditions under which the heat treatment is applied to the substructure 2.

The microbubbles or microcavities 7 generated may have a volume such that they are open on the side facing the face 3a of the substrate 3 and/or on the side facing the external face of the intermediate layer 4. The microbubbles or microcavities 7 may furthermore, optionally, be open towards one another so as to constitute channels, particularly open channels, on the end edges of the intermediate layer 4.

The thermal oxide film 6 may advantageously constitute a barrier for preventing the diffusion of species, in the example phosphorus and/or boron, between the substrate 3 and the intermediate layer 4.

At the end of the aforementioned second step, a chemical cleaning treatment, for example a chemical cleaning of the RCA type known per se, may advantageously be carried out on the surface of the intermediate layer 4. Complementarily, it may be advantageous to carry out, before or after this cleaning treatment, a chemical-mechanical polishing (CMP) operation on the surface of the intermediate layer 4. A complementary layer could also be added. The purpose of these operations is in particular to promote the direct (molecular adhesion) bonding provided later.

According to the third aforementioned step, the structure 1 may be obtained in the following manner, carrying out the following treatments.

The superstrate 5 may consist of a single-crystal silicon wafer, the thickness of which may be a few hundred microns, for example between five hundred and one thousand microns.

Starting from such a superstrate 5, the process preferably continues with an oxidation so as to obtain a thermal silicon oxide film 8 on the face 5a, this film 8 possibly being obtained in an oxidation furnace at a temperature between 950° C. and 1100° C. and possibly having a thickness of between 0.5 and 3 microns. However, the layer 6 could be made of silicon nitride or of silicon oxynitride.

Optionally, an RCA chemical cleaning treatment and a chemical-mechanical polishing (CMP) operation may advantageously be carried out on the surface 5a obtained.

Thereafter, the substructure 2 and the superstrate 5 are joined together by bringing the oxidized face 5a of the superstrate 5 into contact with the intermediate layer 4 so as to obtain direct bonding. Other bonding techniques could be employed, for example anodic bonding or by bonding using an intermediate adhesive layer.

According to the aforementioned optional fourth step, it may be advantageous to carry out a complementary heat treatment on the structure 1 mounted in a furnace. This complementary heat treatment may for example be carried out at a temperature between 200° C. and 1200° C.

In particular, the heat treatment may be carried out at a chosen temperature for two hours and in an argon and oxygen or nitrogen atmosphere.

This complementary heat treatment may in particular have the purpose of increasing the energy of the bonds at the bonding interface of the structure 1 thus assembled and constitutes a consolidating heat treatment. This complementary heat treatment may possibly induce a complementary transformation of the intermediate layer 4.

The thermal oxide film 8 may advantageously constitute a barrier for preventing the diffusion of species, in the example phosphorus and/or boron, between the intermediate layer 4 and substrate 5 and/or between the intermediate layer 4 and the superstrate 5.

In so doing, what is finally obtained is a structure 1 made up of a silicon substrate 2 and a silicon superstrate 3 separated by an intermediate layer 4 made of an electrically insulating material.

The structure 1 has the following advantages.

The intermediate layer 4 is weakened but remains sufficiently strong, and the interfacial bonds between the intermediate layer 4 and, on the one hand, the substrate 3 and, on the other hand, the superstrate 5 are sufficiently strong for subsequent mechanical and/or chemical and/or electromechanical and/or electrochemical and/or mechano-chemical and/or thermal treatments to be applied to the structure 1 in accordance with the processes normally used in microelectronics, without however degrading too significantly the intermediate layer 4 and said interfacial bonds.

The oxide films 6 and 8 constitute barriers for preventing the diffusion of species, in the example phosphorus and/or boron, between the intermediate layer 4 and, on the one hand, the substrate 3 and, on the other hand, the superstrate 5 during the subsequent applied treatments.

According to one embodiment, the substrate 3 may be considered as a support and subsequent treatments may be carried out on the superstrate 5. According to another embodiment, the superstrate 5 may be considered as a support and subsequent treatments may be carried out on the substrate 3. It would also be possible to combine these two embodiments.

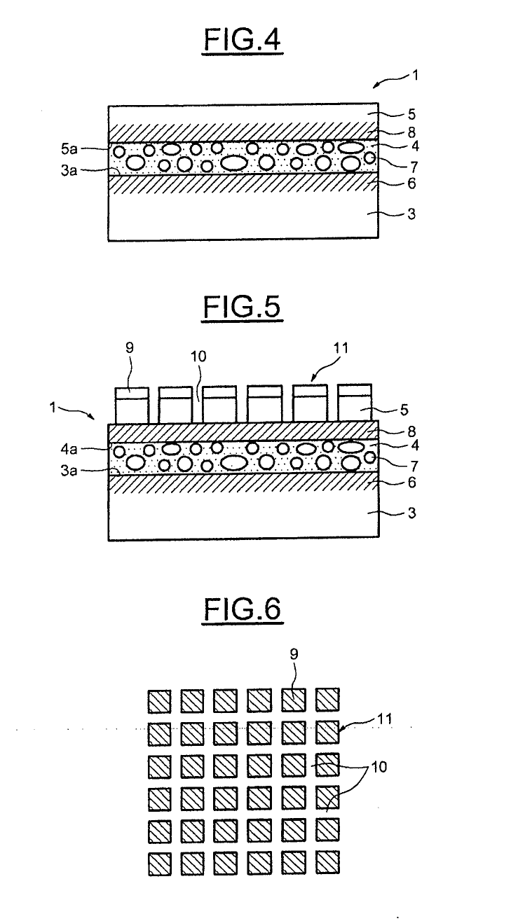

To obtain, at the end of subsequent treatment, a treated thin superstrate, for example with a thickness lying between a fraction of a micron and a few tens of microns, it is possible either to attach a thin superstrate 5 to the intermediate layer 4 or to attach a thick superstrate 5 and then, as shown in FIG. 4, reduce its thickness. Such a thickness reduction may be carried out by means of known grinding, chemical etching or chemical-mechanical polishing techniques and may also be obtained by a cleaving technique, for example by the process known today by the trademark Smart-Cut.

A trimming operation could also be carried out on the superstrate 5 so as to obtain edges of high quality.

The structure 1 may be used for the production of electronic or optoelectronic or MEMS-type integrated circuits or components on the silicon superstrate 5, as such or thinned.

Having for example produced such circuits, the treated superstrate 5 can then be separated.

To do this, forces may be applied between the substrate 3 and the superstrate 5, by any known means and for example by inserting a thin blade between the substrate 3 and the superstrate 5 or by a very high-pressure water jet, which thus mechanically breaks the intermediate layer 4, this breaking being facilitated by the presence of the microbubbles or microcavities 7 in the intermediate layer 4.

Chemical etching may also be carried out, in a bath, on the intermediate layer 4 starting from its edges, for example by means of a solution based on hydrofluoric acid, which can easily advance between the substrate 3 and the superstrate 5 thanks to the presence of the microbubbles or microcavities 7. To promote this chemical etching, it would be possible beforehand to produce holes in various locations in the substrate and/or in the superstrate, reaching the intermediate layer 4.

The superstrate 5 may also be separated by a combination of a mechanical breaking action and chemical etching of the intermediate layer 4, and optionally of a thermal action.

One particular way of separating the substrate 3 and the superstrate 5 will now be described with reference to FIGS. 5, 6 and 7.

As shown in FIGS. 5 and 6, components or circuits 9 arranged for example in a square matrix and spaced apart, may be produced, by any known process, on the thin or thinned superstrate 5. Next, it is possible to produce, for example by suitable chemical etching, grooves or etched features 10 in two perpendicular directions, reaching the oxide layer 8 and allowing the chips 11 having the components or circuits 9 to be singularized.

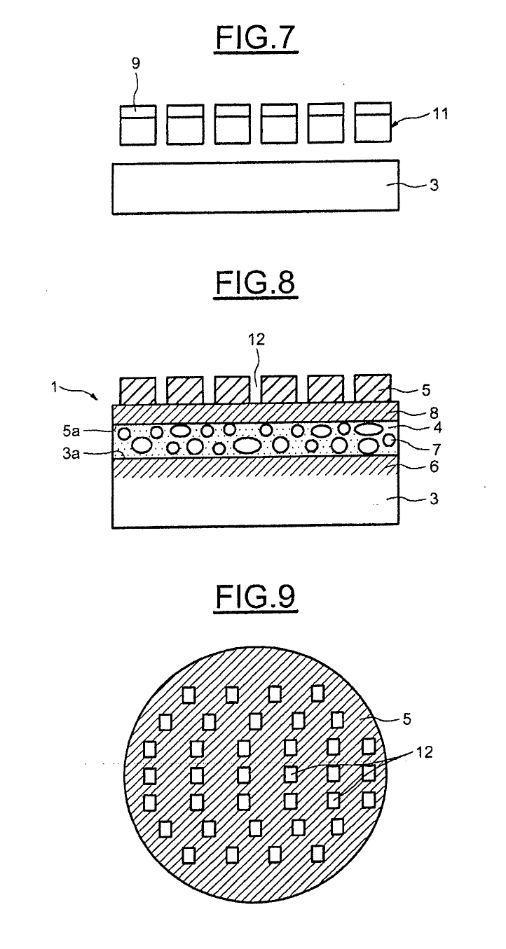

Next, as shown in FIG. 7, the structure 1 thus treated may be immersed in a suitable bath for chemically etching the intermediate layer 4 and the oxide layer 8 in such a way that the various chips 11 bearing the various components or circuits 9 are separated or individualized. This chemical etching is facilitated by the presence of the grooves 10.

Another particular method of separating the substrate 3 and the superstrate 5 will now be described with reference to FIGS. 8 and 9.

Through-holes 12 may be produced through the thin or thinned superstrate 5, reaching the oxide layer 8, these holes being arranged at will one with respect to another. In one embodiment, the holes 12 may be rectangular and arranged in perpendicular lines so as to partly define volumes distributed in a square matrix.

Next, as in the case shown in FIG. 7, the structure 1 thus treated may be immersed in a bath for chemically etching the intermediate layer 4 in such a way that the superstrate 5 is separated and constitutes an apertured wafer. This chemical etching is facilitated by the presence of the holes 12.

Of course, the substrate 3 may be used again as support for a new superstrate 5.

In another embodiment, the grooves, holes or etched features could also be produced through the oxide layer 8 and reach the intermediate layer 4.

The process is particularly applicable to the production of detachable structures, the substrate and/or the superstrate of which may be chosen not only from those indicated above but also especially from silicon, semiconductor materials of III-V class, silicon carbide (SiC) or gallium nitride (GaN).

Obviously, throughout the foregoing text and in the appended claims, the term “substrate” and the term “superstrate” are equivalent and may replace each other.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. Process for fabricating a structure in the form of a wafer, comprising at least a substrate, a superstrate and at least one intermediate layer interposed between the substrate and the superstrate, the process comprising:
forming, on a substrate, at least one intermediate layer comprising at least one base material in which extrinsic atoms or molecules are distributed, these differing from the atoms or molecules of the base material, so as to constitute a substructure;
applying a base heat treatment to this substructure such that, in the temperature range of this heat treatment, the presence of the chosen extrinsic atoms or molecules in the chosen base material causes a structural transformation of said intermediate layer; and
in joining a superstrate to said heat-treated intermediate layer so as to obtain said structure in the form of a wafer.

2. Process according to claim 1, further comprising applying a complementary heat treatment to said structure, consolidating the bond between the superstrate and said intermediate layer and/or inducing a complementary structural transformation of said intermediate layer.

3. Process according to claim 1, wherein said heat treatment causes mechanical and/or chemical and/or thermal weakening of said intermediate layer.

4. Process according to claim 1, wherein the heat treatment of said intermediate layer causes microbubbles or microcavities to form in this layer.

5. Process according to claim 1, wherein the substrate and/or the superstrate are made of single-crystal silicon and the intermediate layer is made of doped silica.

6. Process according to claim 1, wherein the substrate and/or the superstrate are made of silicon, of a semiconductor material of III-V class, of silicon carbide (SiC) or of gallium nitride (GaN).

7. Process according claim 1, wherein the base material of said intermediate layer is silica and the extrinsic atoms of this layer are phosphorus or boron atoms, thus forming a phosphosilicate glass (PSG) or borophosphosilicate glass (BPSG) intermediate layer.

8. Process according to claim 7, wherein the phosphorus concentration is between 6% and 14%.

9. Process according to claim 7, wherein the boron concentration is between 0 and 4%.

10. Process according to claim 1, wherein the heat treatment is carried out at a temperature between 400° C. and 1200° C., preferably between 900° C. and 1200° C.

11. Process according to claim 1, further comprising attaching the superstrate to said intermediate layer by direct (molecular adhesion) bonding.

12. Process according to claim 6, wherein the substrate and/or the superstrate include, respectively, on the side of said intermediate layer, a thermal silicon oxide.

13. Process according to claim 5, wherein at least some of said microbubbles or microcavities are open cells and constitute, at least for some of them, channels.

14. Process according to claim 1, further comprising reducing the thickness of said superstrate and/or said substrate.

15. Process according to claim 1, further comprising producing integrated circuits or components on said superstrate and/or said substrate.

16. Process according to claim 1, further comprising producing grooves and/or etched features through the superstrate and/or the substrate.

17. Process for separating the substrate and the superstrate from the structure obtained by the process according to claim 1, the separation process comprising applying forces between the substrate and the superstrate so as to break the intermediate layer between the substrate and the superstrate.

18. Process for separating the substrate and the superstrate from the structure obtained by the process according to claim 1, the separation process comprising chemically etching said intermediate layer so as to obtain at least partial removal of this intermediate layer between the substrate and the superstrate.

19. Process for separating the substrate and the superstrate from the structure obtained by the process according to claim 1, the separation process comprising applying a heat treatment causing said intermediate layer to weaken so as to break the intermediate layer between the substrate and the superstrate.

20. Process for separating the substrate and the superstrate from the structure obtained by the process according to claim 1, the separation process comprising applying forces between the substrate and the superstrate and/or in chemically etching said intermediate layer and/or in applying a heat treatment to said intermediate layer.

21. Application of the process according to claim 1 to the fabrication of detachable structures for the purpose of producing electronic and/or optoelectronic and/or MEMS-type integrated circuits.
